(19) United States
(12) Patent Application Publication
(10) Pub. No.: US 2009/0034209 A1
(43) Pub. Date: Feb. 5, 2009

(54) MULTI-MODULE COMBINATION TYPE PORTABLE ELECTRONIC DEVICE

(75) Inventors: Jong-sung Joo, Seongnam-si (KR); Bo-oun Park, Seongnam-si (KR)

Correspondence Address: STANZIONE & KIM, LLP, 919 18TH STREET, N.W., SUITE 440, WASHINGTON, DC, 20006, US

(73) Assignee: Samsung Electronics Co., Ltd., Suwon-si (KR)

(21) Appl. No.: 12/020,614

(22) Filed: Jan. 28, 2008

(30) Foreign Application Priority Data
Aug. 3, 2007 (KR) 2007-78187

(51) Int. Cl. H05K 7/00

(52) U.S. Cl. 361/729

(57) ABSTRACT

A multi-module combination type portable electronic device includes a display module having a display unit to display an image, a control module having a plurality of buttons, and a connection unit to connect the display module and the control module, thereby transmitting a data signal and power from the control module to the display module, and thus, enabling use in a plurality of modes according to a combination position of the display module and the control module.

### CROSS-REFERENCE TO RELATED APPLICATIONS

This application claims priority under 35 U.S.C. §119(a) from Korean Patent Application No. 10-2007-0078187, filed on Aug. 3, 2007, in the Korean Intellectual Property Office, the disclosure of which is incorporated herein in its entirety by reference.

### BACKGROUND OF THE INVENTION

1. Field of the Invention

The present invention relates to a portable electronic device, and more particularly, to a multi-module combination type portable electronic device capable of being used in various modes according to a combination position of a plurality of modules which constitute the multi-module combination type portable electronic device.

2. Description of the Related Art

Various portable electronic devices, such as cellular phones, Personal Digital Assistants (PDAs), and the like, can be easily carried by users and become popular. It is possible to combine various functions for electronic devices by installing functions for a digital camera and a music reproducing device such as an MPEG Audio Layer-3 (MP3) player in a single portable electronic device, and adding a function for Digital Multimedia Broadcasting (DMB) thereto so that users can watch DMB.

Such portable electronic devices have become necessities, and users desire the portable electronic devices to be more conveniently constructed.

In particular, a method of combining portable electronic devices having different functions to enable the portable electronic devices to perform the different functions is also desired. In such a case, a display method may be different according to modes to be used. For example, in a movie watching mode, a movie may be required to be watched using an image ratio of 16:9. In a game playing mode, it may be required for the game to be displayed using the ratio of 16:9, or in a manner in which a vertical dimension is wider than a horizontal dimension. In a music listening mode, a vertical dimension may be required to be wider than a horizontal dimension.

As described above, since displaying devices are required to be used in various forms according to desired modes, whenever the modes are changed, the changing of the modes has to be recognized.

### SUMMARY OF THE INVENTION

The present general inventive concept provides a multi-module combination type portable electronic device comprising a plurality of modules which independently operate, the multi-module combination type portable electronic device capable of easily changing execution modes by connecting the plurality of modules to different facing sides of the respective modules.

Additional aspects and utilities of the present general inventive concept will be set forth in part in the description which follows and, in part, will be obvious from the description, or may be learned by practice of the general inventive concept.

The foregoing and/or other aspects and utilities of the present general inventive concept may be achieved by providing a multi-module combination type portable electronic device, including a display module having a display unit for displaying an image, a control module having a plurality of buttons, and a connection unit to connect the display module and the control module, and thereby transmitting a data signal and power from the control module to the display module, wherein the multi-module combination type portable electronic device is capable of being used in a plurality of modes, according to a combination position of the display module and the control module.

The foregoing and/or other aspects and utilities of the present general inventive concept may also be achieved by providing a multi-module combination type portable electronic device, including a display module comprising a display unit to display an image, and a control module connectable to the display module to control the display module according to a combination position of the display module and the control module.

The control module may include a button unit to generate a signal to control the display module according to one of a first type and a second type of an electronic device.

The control module may include a button unit having a character to represent a function of one of the display module and the control module, and the character is disposed in a same reading direction regardless of the combination position of the display module and the control module.

The control module may include a button unit having a reading direction to read a character of the button unit, the display module may include a screen having a watching direction, and the combination position of the display module and the control module may include a position wherein the reading position and the watching position are parallel to each other.

The control module may include a button unit having a reading direction to read a character of the button unit, the display module may include a screen having a width and a height represent a ratio, and the combination position of the display module and the control module may include a position wherein the reading position is parallel to a direction of the height of the display module and a second position wherein the reading position is parallel to a direction of the width of the display module.

The electronic device may further include a connection unit to connect the display module and the control module, and to transmit a data signal and power from the control module to the display module.

A combination of the display module and the control module may include one of a first type of an electronic device and a second type of an electronic device according to the combination position of the display module and the control module.

A combination of the display module and the control module may be used as an electronic device having a plurality of modes according to the combination position of the display module and the control module.

The combination position of the display module and the control module may include a first combination position of a side of the display module and a first side of the control module, and a second combination position of the side of the display module and a second side of the control module.

The display module may include a display interface, the control module may include a first interface and a second interface, and the combination position of the display module and the control module may include a first combination of the display interface of the display module and the first interface of the control module, and a second combination of the display interface of the display module and the second interface of the control module.

The display module may include a display interface, the control module may include a button unit in a reading direction, and a control interface to communicate with the display interface, and the combination position of the display module and the control module may include a first combination wherein the display interface of the display module and the first interface of the control module are disposed parallel to the reading direction, and a second combination where the display interface of the display module and the second interface of the control module are disposed perpendicular to the reading direction.

The control module may control the display module to display an image according to one of a first ratio and a second ratio.

The display module may include a first ratio and a second ratio to display an image, and the control module may generate a first signal to correspond to the first ratio of the image and a second signal to correspond to the second ratio of the image to the display module according to the combination position of the display module and the control module.

The image may include a first image having a first ratio and a second image having a second ratio, and the control module may output a first image signal and a first power signal to correspond to the first image, and a second image signal and a second power signal to correspond to the second image.

The first image signal and the second image signal may be different, and the first power signal and the second power signal may be same.

The electronic device may include a processor installed in one of the display module and the control module to process a signal to correspond to the image.

The electronic device may include a speaker unit installed in one of the display module and the control module to process a sound signal to correspond to the image.

The electronic device may include a receiving unit installed in one of the display module and the control module to receive a signal to correspond to the image.

The electronic device may include a receiving unit installed in one of the display module and the control module to reproduce a signal to correspond to the image.

The foregoing and/or other aspects and utilities of the present general inventive concept may also be achieved by providing a multi-module combination type portable electronic device, including a display module connectable to an external control module to display an image according to a combination position of the display module and the control module.

The foregoing and/or other aspects and utilities of the present general inventive concept may also be achieved by providing a multi-module combination type portable electronic device, including a control module connectable to an external display module to control the display module according to a combination position of the display module and the control module.

The foregoing and/or other aspects and utilities of the present general inventive concept may also be achieved by providing a method of a multi-module combination type portable electronic device, the method including providing a display module comprising a display unit to display an image, connecting the display module and a control module, and controlling the display module using the control module according to a combination position of the display module and the control module.

The foregoing and/or other aspects and utilities of the present general inventive concept may also be achieved by providing a method of a multi-module combination type portable electronic device, the method including proving a display module to be connectable to an external control module, and displaying an image according to a combination position of the display module and the control module.

The foregoing and/or other aspects and utilities of the present general inventive concept may also be achieved by providing a method of a multi-module combination type portable electronic device, the method including providing a control module to be connectable to an external display module, and controlling the display module according to a combination position of the display module and the control module.

The foregoing and/or other aspects and utilities of the present general inventive concept may also be achieved by providing a computer-readable medium to contain computer-readable codes as a program to execute a method of a multi-module combination type portable electronic device, the method including providing a display module comprising a display unit to display an image, connecting the display module and a control module, and controlling the display module using the control module according to a combination position of the display module and the control module.

### BRIEF DESCRIPTION OF THE DRAWINGS

The above and other aspects and utilities of the present general inventive concept will become more apparent by describing in detail exemplary embodiments thereof with reference to the attached drawings in which:

FIG. 1 is a diagram illustrating a display module and a control module which are separated from each other;

FIG. 2 is a diagram illustrating a video player created by combining a display module with a control module according to an embodiment of the present general inventive concept;

FIG. 3 is a diagram illustrating a music player created by combining a display module with a control module according to another embodiment of the present general inventive concept;

FIG. 4 is a diagram illustrating a game player created by combining a display module with a control module having a plurality of buttons for performing a game according to another embodiment of the present general inventive concept;

FIG. 5 is a diagram illustrating a game player created by combining a different side of the control module of FIG. 4 with a display module according to another embodiment of the present general inventive concept;

FIG. 6 is a diagram illustrating a multimedia broadcasting device created by combining a display module with a control module having a plurality button for watching DMB according to another embodiment of the present general inventive concept;

FIG. 7 is a diagram illustrating a multimedia broadcasting device created by combining a different side of the control module of FIG. 5 with a display module according to another embodiment of the present general inventive concept;

FIGS. 8 and 9 are diagrams illustrating a connection unit according to another embodiment of the present general inventive concept;

FIG. 10 is a diagram illustrating a connection unit according to another embodiment of the present general inventive concept;

FIG. 11 is a diagram illustrating a connection unit according to another embodiment of the present general inventive concept; and

FIG. 12 is a block diagram illustrating a multi-module combination type portable electronic device according to another embodiment of the present general inventive concept.

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept by referring to the figures.

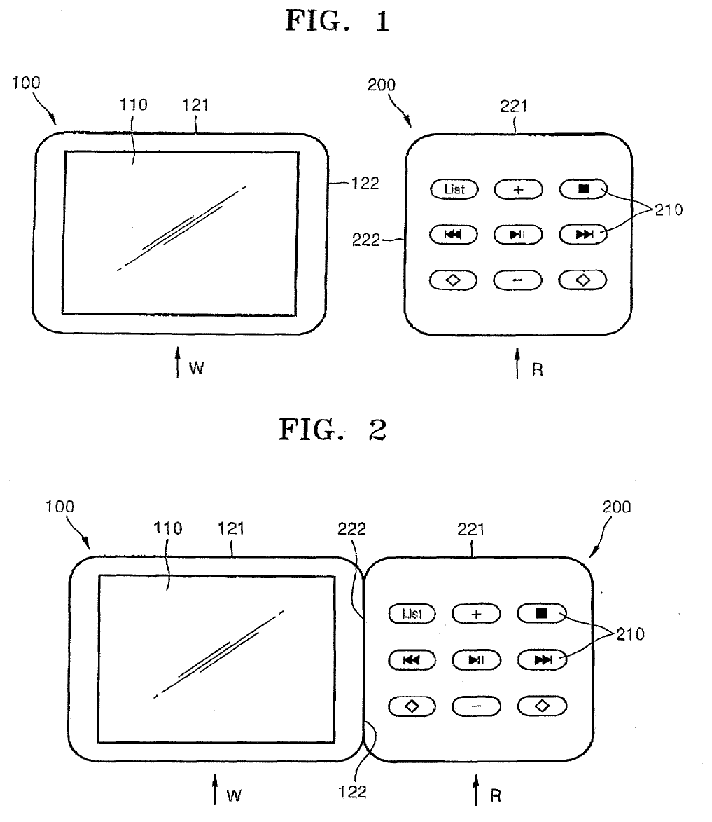

FIG. 1 is a diagram illustrating a display module 100 and a control module 200 which are separated from each other.

Referring to FIG. 1, the display module 100 includes a display unit 110 to display an image. A horizontal side 121 (hereinafter referred to as ‘a long side’) of the display module 100 is formed to be longer than a vertical side 122 (hereinafter referred to as ‘a short side’) of the display module 100. Thus, a horizontal side of the display unit 110 is also formed to be longer than a vertical side of the display unit 110, and its ratio may be 16:9. Various types of displays, such as a Thin Film Transistor-Liquid Crystal Display (TFT-LCD) to display an image may be applied to the display unit 110, but the present general inventive concept is not limited thereto. Also, a size or dimension of the display unit 110 may be changed.

The control module 200 includes a button unit 210 to generate one or more commands. The control module 200 has a shape, for example, a square including a first side 221 and a second side 222. The first side 221 and the second side 222 may have a same length. However, the present general inventive concept is not limited thereto but may have various forms. The control module 200 is an independent device capable of operating as a remote controller or a shuffle player.

When a plurality of modules which independently operate as described above are combined with each other, the combination of the modules may be changed into a video player, a music player, a game player, and a Digital Multimedia Broadcasting (DMB), according to relative combination positions of the modules. That is, after the plurality of modules are combined with each other, modes are changed according to the combination position of the modules, without performing a separate modes changing procedure, whereby the various combinations of the modules may be used as various portable electronic devices.

FIG. 2 is a diagram illustrating a video player created by combining the display module 100 with the control module 200 according to an embodiment of the present general inventive concept.

Referring to FIGS. 1 and 2, a short side 122 of the display module 100 is combined with the second side 222 of the control module 200. Since the display module 100 is formed to have a long side 121 that is longer than the short side 122, the display module 100 is combined with the control module 200, thereby becoming a video player to display an image such that a user watches the image. By operating the button unit 210 of the control module 200, various functions such as playing an image, stopping the image, pausing the image, or skipping the image may be executed. Although FIG. 2 illustrates the control module 200 combined with a right side of the display module 100 in FIG. 2, for conveniences of users, the control module 200 may be combined with a left side of the display module 100.

The button unit 210 of the control module 200 may have one or more buttons each having a character to represent a function of the corresponding button, and the character can be disposed on the corresponding button such that a user located in a reading position R can properly read the character of the button in a reading position. The character may be seen as being rotated with respect to the user when the user is not in the reading position in the reading direction.

Accordingly, when the control module 200 is combined with the display module 100, the control module 200 is disposed to show the buttons in the reading position as illustrated in FIG. 2. And the image can be displayed on a screen of the display unit of the display module 100 according to an image ratio of a screen size or dimension of the display unit 110 as illustrated in FIG. 2, and the user can watch the displayed image in a washing direction W.

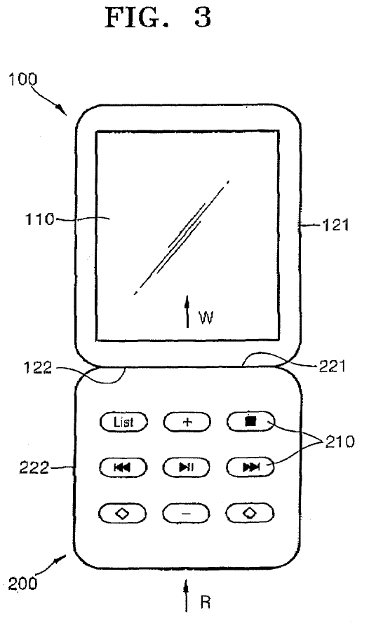

FIG. 3 is a diagram illustrating a music player created by combining the display module 100 with the control module 200 according to another embodiment of the present general inventive concept.

Referring to FIGS. 1, 2, and 3, the short side 122 of the display module 100 is combined with the first side 221 of the control module 200. The long side 121 of the display module 100 is located parallel to a vertical direction in FIG. 3, such that the combination of the display module 100 and control module 200 becomes a music player capable of displaying a title, a list, or lyrics of music to be reproduced while reproducing the music. The display module 100 may be also used as a display module to display an image of the music player.

At least one of the display module 100 and the control module 200 includes a sound processor to process and generate a sound signal, such as the music, and/or an image processor to process and generate an image signal corresponding to the sound signal. It is possible that at least one of the display module 100 and the control module 200 includes a speaker or a speaker terminal connected to the sound processor to reproduce the sound.

As described above, although FIG. 3 illustrates a different side of the control module 200 combined with the display module 100 compared to FIG. 2 illustrating a side of the control module 200 combined with the display module 100, the control module 200 is disposed to show the buttons at a reading position in the reading direction as illustrated in FIG. 3. And the image can be displayed on a screen of the display unit 110 of the display module 100 according to an image ratio of a screen size or dimension of the display unit 110 as illustrated in FIG. 3, and the user can watch the displayed image in the watching direction.

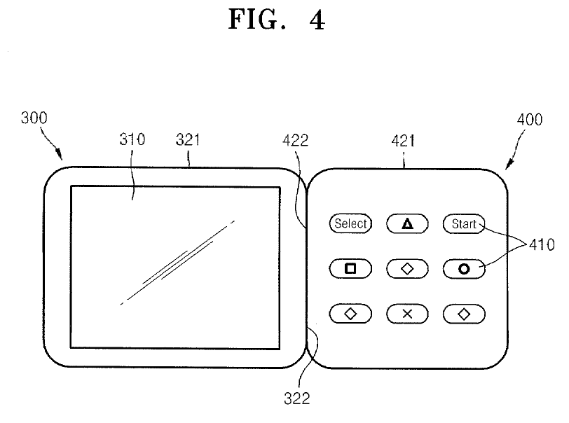

FIG. 4 is a diagram illustrating a game player created by combining a display module 300 with a control module 400 having a button unit 410 for operating a game, according to another embodiment of the present general inventive concept.

Referring to FIG. 4, the game player is similar to the video player illustrated in FIG. 2. However, the control module 400 includes a button unit 410 suitable to perform a game.

Accordingly, the button unit 410 may have different buttons. However, it is possible that the function of the respective buttons can be changed between the function of the button unit 110 and the function of the button unit 410. In this case, the characters of the buttons can be displayed or replaced to perform the corresponding function according to a selection of a predetermined button of the button unit 110 and the button unit 410. Here, at least a predetermined number of the buttons can be a touch screen to generate the commands to correspond to the functions of the respective buttons of the button unit 110 and the button unit 410 to perform the corresponding function.

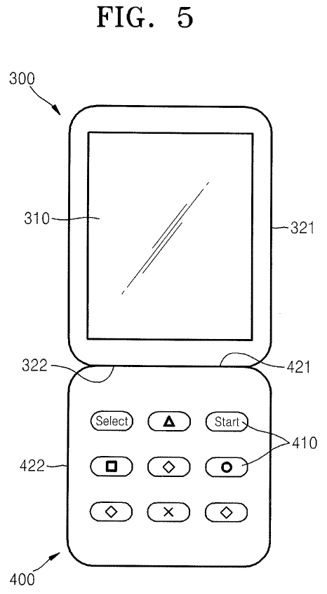

A short side 322 of the display module 300 is combined with a second side 422 of the control module 400. Since the display module 300 is formed to have a long side 321 that is longer than the short side 322, the display module 300 is combined with the control module 300, thereby becoming a game player on which a game can be played. For this purpose, the control module 400 has a plurality of buttons 410 capable of operating a game, and the game may be played by operating the buttons 410. Although the control module 400 is rightward combined with the display module 300, for conveniences of users, the control module 400 may be leftward combined with the display module 300. The display module 300 illustrated in FIG. 4 has the long side 321 longer than the short side 322. However, according to the game to be played, a vertical side may be required to be longer than a horizontal side. For this purpose, as illustrated in FIG. 5, a method of rotating the display module 300 of FIG. 4 by 90 degrees and combining with the control module 400 may be used.

FIG. 5 is a diagram illustrating a game player created by combining a different side of a control module 400 of FIG. 4 with a display module 300, according to another embodiment of the present general inventive concept.

Referring to FIGS. 4 and 5, a short side 322 of the display module 300 is combined with a first side 421 of the control module 400. Since a long side 321 of the display module 300 is located parallel to a vertical direction in FIG. 5, the game player may be operated as a game player capable of being used in a game in which a length in a vertical direction is required to be longer than a length in a horizontal direction.

As described above, when the short side 322 of the display module 300 is combined with one of the first side 421 and the second side 422 of the control module 400 in the reading direction, a user can watch the image in the watching direction and read the buttons in the reading direction.

Although FIG. 4 illustrates that the short side 322 of the display module 300 is parallel to the reading direction of the control module 400, FIG. 5 illustrates that the long side 321 of the display module 300 is parallel to the reading direction of the control module 400 such that a user can watch the image in the reading direction in a position in the reading direction regardless the combination position of the display module 300 and the control module 400. Here, the second side 422 of the control module 400 is disposed to have an angle with the reading direction, for example, perpendicular to the reading direction, and the first side 421 of the control module 400 is disposed perpendicular to the reading direction.

Meanwhile, since a broadcasting signal, such as DMB, becomes more popular, a demand for a DMB receiver capable of being conveniently carried has greatly increased. For this purpose, a display module may be easily combined with a control module, so that a user can watch DMB while moving.

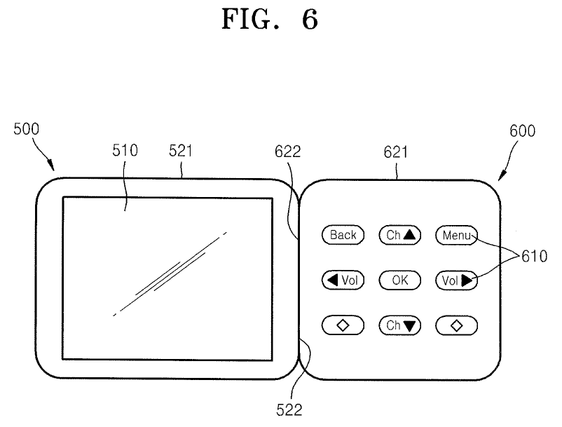

FIG. 6 is a diagram illustrating a multimedia broadcasting device created by combining a display module 500 with a control module 600 having a plurality of buttons to control DMB according to another embodiment of the present general inventive concept.

Referring to FIG. 6, a short side 522 of the display module 500 is combined with a second side 622 of the control module 600. The display module 500 is combined with the control module 600, thereby operating as a multimedia broadcasting device on which an image can be watched. For this purpose, the control module 600 has a plurality of buttons 610 capable of operating a function for watching DMB. By operating the plurality of buttons 610, a function for watching DMB may be executed. Although the control module 600 is rightward combined with the display module 500 in FIG. 6, for convenience of users, the control module 600 may be leftward combined with the display module 500.

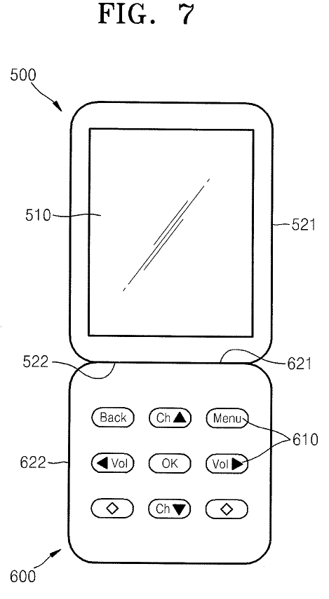

FIG. 7 is a diagram illustrating a multimedia broadcasting device created by combining a different side of the control module 600 of FIG. 5 with a display module 500 according to another embodiment of the present general inventive concept.

Referring to FIG. 7, a short side 522 of the display module 500 is combined with a first side 621 of the control module 600. Since a long side 521 of the display module 500 is located parallel to a vertical direction in FIG. 7, the combination of the display module 500 and control module 600 operates as the multimedia broadcasting device.

Various modes capable of being used as the video player, the music player, the game player, and the multimedia broadcasting device enabled by combining a display module with a control module are described above. In this regard, a method of connecting mutually independent devices as a single device is required. Thus, hereinafter, the method will now be explained. The various modes are explained in relation to FIGS. 2 though 7. Since the various modes are changed according to a control module, hereinafter, for convenience of explanation, the method will now be explained by referring to embodiments illustrated in FIGS. 2 and 3.

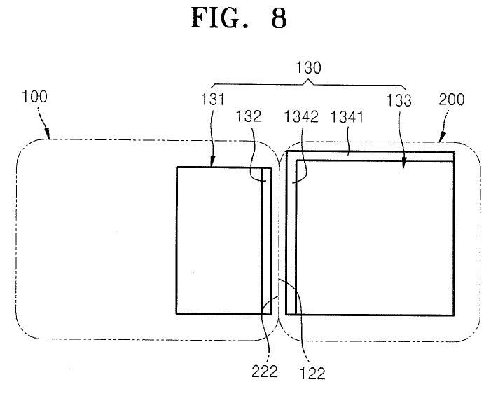

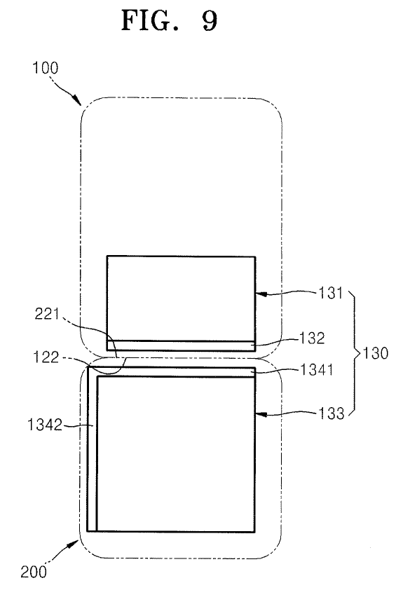

FIGS. 8 and 9 are diagrams illustrating a connection unit 130 usable with an electronic apparatus having a plurality of modules according to another embodiment of the present general inventive concept.

Referring to FIGS. 1, 2, 3, and 8, the short side 122 of the display module 100 and the second side 222 of the control module 200 of FIG. 2 are connected by using the connection unit 130. The connection unit 130 includes a short-range wireless communication chip 131 and a short-range wireless communication chip 133. The short-range wireless communication chip 131 located in the display module 100 includes a magnet unit 132 disposed to face the short side 122. The short-range wireless communication chip 133 located in the control module 200 includes magnet units 1341 and 1342 respectively disposed to face the first side 221 and the second side 222.

The magnet units 132 and 1342 have different polarities, and thus, the display module 100 and the control module 200 are electronically or physically coupled or attached to each other by magnetism between the magnet units 132 and 1342.

A short-range wireless communication chip that is used as a connection unit in the present invention is based on a Near-Field Wireless (NFW) technology that enables transmission of data signals and power between chips, without connection wires. The NFW technology is noted as a standard technology, and those of ordinary skill in the art can easily obtain and embody the NFW technology, thus, further explanation is omitted.

Hence, the short-range wireless communication chips 131 and 133 using the NFW technology may transmit data signals and power, although the short-range wireless communication chips 131 and 133 are separated from each other by a predetermined distance. The purpose of adhering the display module 100 and the control module 200 together is for convenience of users. Thus, the magnet unit 132 is prepared in the short-range wireless communication chip 131 of the display module 100, and the magnet units 1341 and 1342 are prepared in the short-range wireless communication chip 133 of the control module 200, such that the display module 100 and the control module 200 are adhered to each other by using the magnetism between the magnet units 132, 1341, and 1342.

Referring to FIGS. 1, 2, 3, 8 and 9, when the short side 122 of the display module 100 is disposed to face the first side 221 of the control module 200, the display module 100 and the control module 200 are coupled or attached to each other due to the magnetism between the magnet units 132 and 1341. According to mode changes as illustrated in FIGS. 8 and 9, when the magnet units 132 and 1342 are combined, the display module 100 and the control module 200 operate as a video player. When the magnet units 132 and 1341 are combined, the display module 100 and the control module 200 operate as a music player.

The magnet unit 132 is supposed to face one of the magnets 1341 and 1342, so that the short-range wireless communication chip 131 of the display module 100 and the short-range wireless communication chip 133 of the control module 200 can be electronically connected to communicate with each other, thereby transmitting and receiving the commands or signals to perform the functions of the display module 100 and the control module 200.

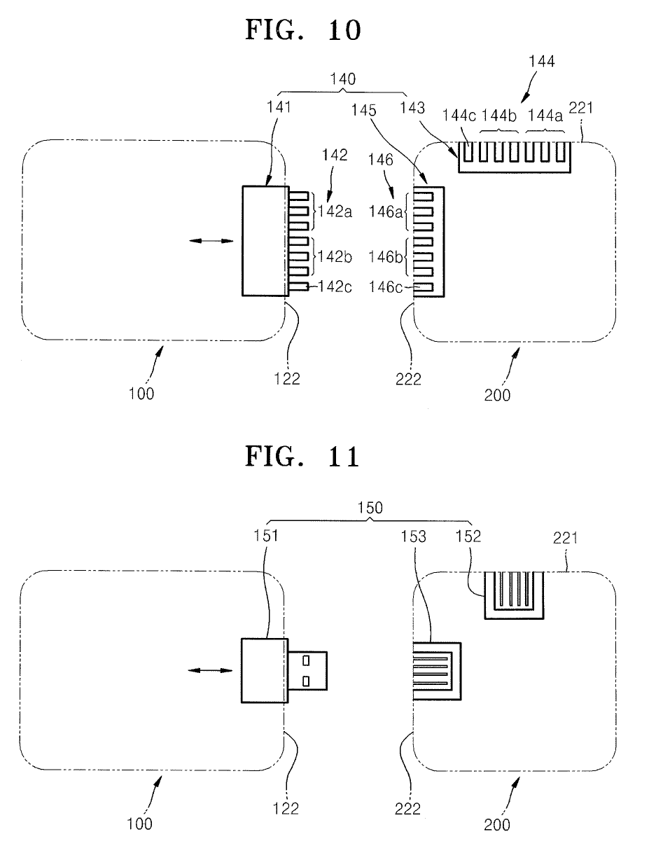

FIG. 10 is a diagram illustrating a connection unit 140 usable with an electronic apparatus having a plurality of modules according to another embodiment of the present general inventive concept.

Referring to FIG. 10, the connection unit 140 may include a first connection unit 141, a second connection unit 143, and a third connection unit 145. The first connection unit 141 located in a short side 122 of the display module 100 includes a reception terminal unit 142 having a plurality of reception terminals. The second connection unit 143 located in a first side 221 of the control module 200 includes a transmission terminal unit 144 capable of combining with the plurality of reception terminals of the reception terminal unit 142. The third connection unit 145 located in a second side 222 of the control module 200 includes a transmission terminal unit 146 capable of combining with the plurality of reception terminals of the reception terminal unit 142.

The plurality of reception terminals of the reception terminal unit 142 include, for example, three current reception terminals 142a, three data reception terminals 1424b, and a mode detection terminal 142c. In correspondence to the plurality of reception terminals of the reception terminal unit 142, a transmission terminal unit 144 of the second connection unit 143 includes, for example, three current transmission terminals 144a, three data transmission terminals 144b, and a mode detection terminal 144c, and a transmission terminal unit 146 of the third connection unit 145 includes, for example, three current transmission terminals 146a, three data transmission terminals 146b, and a mode detection terminal 146c.

The plurality of reception terminals of the reception terminal unit 142 are formed as a protruding type terminal, and the transmission terminals of the first and second terminal units 144 and 146 are formed as concave type terminals capable of combining with the protruding type terminal. The present general inventive concept is not limited thereto but the transmission terminals of the first and second transmission terminal units 144 and 146 may be formed as protruding type terminals, and the plurality of reception terminals of the reception terminal unit 142 may be formed as a concave type terminal. Also, the number of the transmission terminals 144 and 146 and the number of the plurality of reception terminals 142 are not limited to the number of those illustrated in FIG. 10.

When the first connection unit 141 is combined with the second connection unit 143, the display module 100 and control module 200 may be used as the music player as illustrated in FIG. 3. When the first connection unit 141 is combined with the third connection unit 145, the display module 100 and control module 200 may be used as the video player as illustrated in FIG. 2.

In this manner, detection of a mode change to a music player or a video player is performed by the mode detection terminals 142c, 144c, and 146c. That is, when the mode detection terminal 142c is combined with the mode detection terminal 144c, the display module 100 and control module 200 are recognized as the music player. When the mode detection terminal 142c is combined with the mode detection terminal 146c, the display module 100 and control module 200 are recognized as the video player.

Meanwhile, the plurality of reception terminals of the reception terminal unit 142 may be installed in the display module 100 by sliding along an arrow direction of FIG. 10. Thus, when the display module 100 is not combined with the control module 200, the plurality of reception terminals 142 are within the display module 100, and when the display module 100 is combined with the control module 200, the plurality of reception terminals 142 may be protruded out of the display module 100.

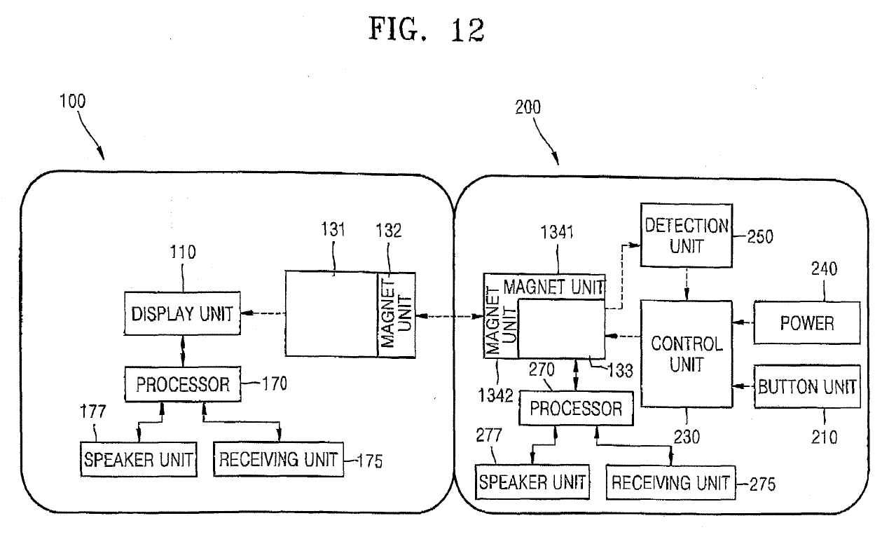

FIG. 11 is a diagram illustrating a connection unit 150 usable with an electronic apparatus having connectable modules according to another embodiment of the present general inventive concept.

Referring to FIG. 11, the connection unit 150 includes a Universal Serial Bus (USB) terminal 151 and USB terminal reception units 152 and 153. The USB terminal 151 is located in a short side 122 of the display module 100. The USB terminal reception unit 152 is located in a first side 221 of the control module 200 and capable of combining with the USB terminal 151. The USB terminal reception unit 153 is located in a second side 222 of the control module 200 and capable of combining with the USB terminal 151.

In the current embodiment of the present invention, the USB terminal 151 is located in the display module 100, and the USB terminal reception units 152 and 153 are located in the control module 200. The present invention is not limited thereto but a plurality of USB terminals may be installed in the control module 200, and in correspondence to this, USB terminal reception units may be installed in the display module 100.

When the USB terminal 151 is combined with the USB terminal reception unit 152, the display module 100 and control module 200 may be used as the music player as illustrated in FIG. 3. When the USB terminal 151 is combined with the USB terminal reception unit 153, the display module 100 and control module 200 may be used as the video player as illustrated in FIG. 2.

In this manner, according to which one of the USB terminal reception units 152 and 153 is combined with the USB terminal 151, a portable electronic device may be used as a music player or a video player.

Meanwhile, the USB terminal 151 may be installed in the display module 100 by sliding along an arrow direction as illustrated in FIG. 11. Thus, when the display module 100 is not combined with the control module 200, the USB terminal 151 is within the display module 100, and when the display module 100 is combined with the control module 200, the USB terminal 151 may be protruded out of the display module 100.

Although FIG. 11 illustrates a USB connection as an interface between the display module 100 and the control unit 200, the present general inventive concept is not limited thereto. It is possible that another type of an interface connection, for example, SATA connection, can be used to allow the display module 100 and the control unit 200 to communicate with each other.

FIG. 12 is a block diagram of a multi-module combination type portable electronic device according to another embodiment of the present general inventive concept.

Referring to FIG. 12, a display module 100 includes a display unit 110 and a short-range wireless communication chip 131 having a magnet unit 132. A control module 200 includes a short-range wireless communication chip 133 having magnet units 1341 and 1342, a detection unit 250 connected to the short-range wireless communication chip 133 to detect one of the magnet units 1341 and 1342 connected to the magnet unit 132 of the display module 100, a control unit 230 to control functions of the control module 200 and/or the display module 100, a button unit 210 to generate one or more commands to correspond to functions of the control module 200 and/or the display module 100, and power 240 to be supplied to the control module 200 and/or the display module.

When the display module 100 and the control module 200 are connected, the detection unit 250 detects which one of the magnet units 1341 and 1342 is connected to the magnet unit 132 of the display module 100, and transmits a result of the detection to the control unit 230.

The control unit 230 is connected to the detection unit 250, the power 240, the button unit 210, and the short-range wireless communication chip 133. The control unit 230 determines modes that are to be used by the combined display module 100 and control module 200, by using a signal transmitted from the detection unit 250. That is, when the magnet unit 1341 of the control module 200 is connected to the magnet unit 132 of the display module 100, the combined display module 100 and control module 200 are recognized as a video player. When the magnet unit 1342 of the control module 200 is connected to the magnet unit 132 of the display module 100, the combined display module 100 and control module 200 are recognized as a music player.

The control unit 230 transmits the power and the operation signal of the button unit 210 to the short-range wireless communication chip 131 of the display module 100, by using the short-range wireless communication chip 133. The power and the operation signal transmitted to the short-range wireless communication chip 131 of the display module 100 are delivered to the display unit 110, whereby an image is displayed.

The block diagram of FIG. 12 may be applied to all cases illustrated in FIGS. 9 through 11. In the case where the block diagram of FIG. 12 is applied to a case illustrated in FIG. 10, the mode detection terminals 142c and 146c correspond to the detection unit 250 of FIG. 12, and the first, second, and third connection units 141,143, and 145 are used instead of the short-range wireless communication chips 131 and 133. In the case where the block diagram of FIG. 12 is applied to a case illustrated in FIG. 11, the USB terminal 151 and USB terminal reception units 152 and 153 are used instead of the short-range wireless communication chips 131 and 133.

The display module 100 may include a processor 170 to communicate with an external device through an interface or a wired or wireless connection therebetween to receive a signal and to generate an image signal to be displayed in the display module as the image and/or to generate a sound signal corresponding to the image. The processor 170 may receive the signal through a receiving unit 175. The receiving unit 175 may be a player to store a storage medium and to reproduce the signal from the storage medium. A conventional storage medium can be used as the storage medium, and a convention player to reproduce data from the conventional storage medium can be used as the receiving unit 175. The display module 100 may further include a speaker unit 177 to receive and generate a sound signal corresponding to the image to be reproduced. The speaker unit 177 may be a speaker or a speaker terminal to transmit the sound signal to an external speaker.

The processor 170 may modify a ratio or size of the image according to the detection of connection between the display module 100 and one of the first side and the second side of the control module 200, so that the image can be displayed according to the screen size of the display unit of the display module in the watching direction.

The control module 200 may include a processor 270 to communicate with an external device through an interface or a wired or wireless connection therebetween to receive a signal and to generate an image signal to be displayed in the display module as the image and/or to generate a sound signal corresponding to the image. The processor 270 may receive the signal through a receiving unit 275. The receiving unit 275 may be a player to store a storage medium and to reproduce the signal from the storage medium. A conventional storage medium can be used as the storage medium, and a conventional player to reproduce data from the conventional storage medium can be used as the receiving unit 275. The control module 200 may further include a speaker unit 277 to receive and generate a sound signal corresponding to the image to be reproduced. The speaker unit 277 may be a speaker or a speaker terminal to transmit the sound signal to an external speaker.

The processor 270 may modify a ratio or size of the image according to the detection of connection between the display module 100 and one of the first side and the second side of the control module 200, so that the image can be displayed according to the screen size of the display unit of the display module in the watching direction.

The control module 200 can generate a first control command to correspond to a first type of image, so that the first type of image can be displayed in the display module as the image in the watching direction, and a second control command to correspond to a second type of image, so that the second type of image can be displayed in the display module as the image in the watching direction. The first control command may be a command to control a first function of the control module and the display module according to a first connection type between the display module and the control module, and the second control command may be a command to control a second function of the control module and the display module according to a second connection type between the display module and the control module.

Although FIG. 12 illustrates the display module 100 having the processor 170, the receiving unit 175, and the speaker unit 177, and the control module 200 having the processor 270, the receiving unit 275, and the speaker unit 277, the display module 100 may have one combination of the processor 170, the receiving unit 175, and the speaker unit 177, and control module 200 may have the other combination of the processor 270, the receiving unit 275, and the speaker unit 277, such that the combination of the display module 100 and the control module 200 can perform the first function of the control module 200 and the display module 100 according to the first connection type between the display module 100 and the control module 200 and can perform the second function of the control module 200 and the display module 100 according to the second connection type between the display module 100 and the control module 200.

The present general inventive concept can also be embodied as computer-readable codes on a computer-readable medium. The computer-readable medium can include a computer-readable recording medium and a computer-readable transmission medium. The computer-readable recording medium is any data storage device that can store data which can be thereafter read by a computer system. Examples of the computer-readable recording medium include read-only memory (ROM), random-access memory (RAM), CD-ROMs, magnetic tapes, floppy disks, and optical data storage devices. The computer-readable recording medium can also be distributed over network coupled computer systems so that the computer-readable code is stored and executed in a distributed fashion. The computer-readable transmission medium can transmit carrier waves or signals (e.g., wired or wireless data transmission through the Internet). Also, functional programs, codes, and code segments to accomplish the present general inventive concept can be easily construed by programmers skilled in the art to which the present general inventive concept pertains.

As described above, the multi-module combination type portable electronic device according to the present general inventive concept can be used as one of first and second electronic devices to perform one of first and second functions of the respective first and second electronic devices.

As described above, the multi-module combination type portable electronic device according to the present general inventive concept can combine a plurality of modules that independently operate, thereby being used as another portable electronic device, and

As described above, the multi-module combination type portable electronic device according to the present general inventive concept can connect the plurality of modules to each other to enable transmittance of power and signals, whereby the plurality of modules are simply combined into one device and used.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A multi-module combination type portable electronic device, comprising:
a display module comprising a display unit to display an image;
a control module comprising a plurality of buttons; and
a connection unit to connect the display module and the control module, and to transmit a data signal and power from the control module to the display module,
wherein the multi-module combination type portable electronic device is used in a plurality of modes according to a combination position of the display module and the control module.

2. The electronic device of claim 1, wherein one side of the display module is combined with one side of the control module to be used as a video player.

3. The multi-module combination type portable electronic device of claim 1, wherein one side of the display module is combined with another side of the control module to be used as a music player.

4. The electronic device of claim 3, wherein the control module comprises a plurality of buttons relating to DMB (Digital Multimedia Broadcasting).

5. The electronic device of claim 3, wherein the control module comprises a plurality of buttons relating to a game.

6. The electronic device of claim 2, wherein the control module comprises a plurality of buttons relating to DMB.

7. The electronic device of claim 2, wherein the control module comprises a plurality of buttons relating to a game.

8. The electronic device of claim 1, wherein the connection unit is installed respectively in the display module and the control module, comprises short-range wireless communication chips respectively comprising magnet units, attaches the display module and the control module to each other by using magnetism between the magnet units, and exchanges power and data signals by using the short-range wireless communication chips.

9. The multi-module combination type portable electronic device of claim 1, wherein the connection unit exchanges power and data signals between the display module and the control module by a USB (Universal Serial Bus) terminal located in the display module, and a USB terminal reception unit which is located in the control module to be connected to the USB terminal.

10. The electronic device of claim 9, wherein the control module further comprises a detection unit to detect the combination position between the display module and the control module.

11. The electronic device of claim 8, wherein the control module further comprises a detection unit to detect the combination position between the display module and the control module.

12. The electronic device of claim 1, wherein the connection unit exchanges power and data signals between the display module and the control module by a first connection unit located in the display module and comprising a plurality of reception terminals, a second connection unit and a third connection unit respectively located in a first side and a second side of the control module and comprising a plurality of transmission terminals to be combined with the plurality of reception terminals.

13. The electronic device of claim 12, wherein:
the transmission terminals comprise one or more current transmission terminals to transmit current, one or more data transmission terminals to transmit a data signal, and one or more mode detection terminals to detect the modes; and
the reception terminals comprise one or more current reception terminals, one or more data reception terminals, and one or more mode detection terminals.

14. The electronic device of claim 13, wherein the first connection unit is slidably installed in the display module such that the first connection unit protrudes out of the display module when the first connection unit is connected with the second and third connection units.

15. The electronic device of claim 12, wherein the first connection unit is slidably installed in the display module such that the first connection unit protrudes out of the display module when the first connection unit is connected with the second and third connection units.

16. A multi-module combination type portable electronic device, comprising:
a display module comprising a display unit to display an image; and
a control module connectable to the display module to control the display module according to a combination position of the display module and the control module.

17. The electronic device of claim 16, wherein the control module comprises a button unit having a character to represent a function of one of the display module and the control module, and the character is disposed in a same reading direction regardless of the combination position of the display module and the control module.

18. The electronic device of claim 16, wherein the control module comprises a button unit having a reading direction to read a character of the button unit, and the display module comprises a screen having a width and a height represent a ratio, and the combination position of the display module and the control module comprises a position wherein the reading position is parallel to a direction of the height of the display module and a second position wherein the reading position is parallel to a direction of the width of the display module.

19. The electronic device of claim 16, further comprising:
a connection unit to connect the display module and the control module, and to transmit a data signal and power from the control module to the display module.

20. The electronic device of claim 16, wherein the combination position of the display module and the control module comprises:
a first combination position of a side of the display module and a first side of the control module; and
a second combination position of the side of the display module and a second side of the control module.

21. The electronic device of claim 16, wherein:
the display module comprises a display interface;
the control module comprises a first interface and a second interface; and
the combination position of the display module and the control module comprises a first combination of the display interface of the display module and the first interface of the control module, and a second combination of the display interface of the display module and the second interface of the control module.

22. The electronic device of claim 16, wherein:
the display module comprises a display interface;
the control module comprises a button unit in a reading direction, and a control interface to communicate with the display interface; and
the combination position of the display module and the control module comprises a first combination wherein the display interface of the display module and the first interface of the control module are disposed parallel to the reading direction, and a second combination where the display interface of the display module and the second interface of the control module are disposed perpendicular to the reading direction.

23. The electronic device of claim 16, wherein:
the display module comprises a first ratio and a second ratio to display an image; and
the control module generates a first signal to correspond to the first ratio of the image and a second signal to correspond to the second ratio of the image to the display module according to the combination position of the display module and the control module.

24. The electronic device of claim 16, wherein:
the image comprises a first image having a first ratio and a second image having a second ratio; and
the control module outputs a first image signal and a first power signal to correspond to the first image, and a second image signal and a second power signal to correspond to the second image.

25. The electronic device of claim 24, wherein the first image signal and the second image signal are different, and the first power signal and the second power signal are same.
